(19) United States
(12) Patent Application Publication
(10) Pub. No.: US 2013/0105889 A1
(43) Pub. Date: May 2, 2013

(54) SWITCHING DEVICE AND METHOD FOR MANUFACTURING THE SAME

(71) Applicants: Hirokazu FUJIWARA, Miyoshi-shi (JP); Hisashi ISHIMABUSHI, Toyota-shi (JP); Yukihiko WATANABE, Nagoya-shi (JP); Narumasa SOEJIMA, Seto-shi (JP); Toshimasa YAMAMOTO, Ichinomiya-shi (JP); Yuuichi TAKEUCHI, Oobu-shi (JP)

(72) Inventors: Hirokazu FUJIWARA, Miyoshi-shi (JP); Hisashi ISHIMABUSHI, Toyota-shi (JP); Yukihiko WATANABE, Nagoya-shi (JP); Narumasa SOEJIMA, Seto-shi (JP); Toshimasa YAMAMOTO, Ichinomiya-shi (JP); Yuuichi TAKEUCHI, Oobu-shi (JP)

(73) Assignees: DENSO CORPORATION, KARIYA CITY (JP); TOYOTA JIDOSHA KABUSHIKI KAISHA, Toyota-shi (JP)

(21) Appl. No.: 13/616,632

(22) Filed: Sep. 14, 2012

(30) Foreign Application Priority Data
Oct. 31, 2011 (JP) 2011-239012

(51) Int. Cl. H01L 21/336; H01L 29/78

(52) U.S. Cl. 257/330; 438/270; 257/E29.262; 257/E21.41

(57) ABSTRACT

A method for manufacturing a switching device, which includes a trench type gate electrode and first to fourth semiconductor regions, is provided. The first semiconductor region is in contact with a gate insulating film and is of n-type. The second semiconductor region is in contact with the gate insulating film, and is of p-type. The third semiconductor region is in contact with the gate insulating film, and is of n-type. The fourth semiconductor region is a p-type semiconductor region which is positioned in a range deeper than the second semiconductor region and consecutive with the second semiconductor region, and which faces the gate insulating film via the third semiconductor region. The manufacturing method includes forming the second semiconductor region in which aluminum is doped, and implanting boron into a range in which the fourth semiconductor region is to be formed in the semiconductor substrate.

### CROSS-REFERENCE TO RELATED APPLICATION

This application claims priority to Japanese Patent Application No. 2011-239012 filed on Oct. 31, 2011, the contents of which are hereby incorporated by reference into the present application.

### TECHNICAL FIELD

The technique disclosed in the present specification relates to a switching device having a trench type gate electrode.

### BACKGROUND

Japanese Patent Application Publication No. 2009-117593 (hereinafter, referred to as a patent document 1) discloses a switching device having a trench type gate electrode. In the switching device, an n-type source region, a p-type base region, and an n-type drift region are formed in a range in contact with a gate insulating film. With a switching device of this type, generally, a high voltage is likely to be applied to a gate insulating film positioned between the gate electrode and the drift region. Therefore, in the switching device of the patent document 1, a p-type deep region is formed under the base region at a position not in contact with the gate insulating film. When a high voltage is applied to the switching device, a depletion layer extends from the deep region toward the gate insulating film to suppress an application of a high electric field to the gate insulating film.

### SUMMARY

The deep region of the switching device according to the patent document 1 is not a region through which a principal current flows. Therefore, forming the deep region in the switching device problematically increases a size of the switching device despite no increase in a maximum conductive current of the switching device. Therefore, the present specification provides a method for manufacturing a switching device which is capable of suppressing an application of a high electric field to a gate insulating film and which has a small size, and a structure of the switching device.

With the switching device according to the patent document 1, when an avalanche breakdown occurs in a semiconductor substrate, holes created by the avalanche breakdown flow into the base region. Accordingly, the holes are rapidly discharged from a region in which the avalanche breakdown had occurred and an increase in an avalanche current is suppressed. In order to rapidly discharge the holes from the region in which the avalanche breakdown had occurred, the base region favorably has a high density of carriers. In addition, as described earlier, the deep region is favorably as small as possible.

Therefore, the inventors focused on p-type impurities for forming the base region and the deep region. Conceivable impurities for forming the base region and the deep region include aluminum and boron.

The inventors discovered the following facts. That is, aluminum has a high activation rate when doped in a semiconductor. Therefore, by forming the base region using aluminum, a base region with a high density of carriers can be formed. On the other hand, aluminum must be doped in the semiconductor by performing ion implantation at a higher energy than in the case of boron. As a result, a variation in implantation positions increases. Therefore, when a deep region is formed using aluminum, a width of the deep region increases, which makes it difficult to downsize a switching device. Meanwhile, boron can be doped in a semiconductor by performing ion implantation at a lower energy than in the case of aluminum and therefore is able to suppress the variation in implantation positions. Therefore, by forming the deep region using boron, a narrow deep region can be formed. In other words, the switching device can be downsized. On the other hand, boron has a low activation rate when doped in a semiconductor. Therefore, when the base region is formed using boron, a density of carriers in the base region decreases. As a result, an avalanche resistance of the switching device declines.

In consideration of the above, the present specification provides a manufacturing method described below which utilizes characteristics of both aluminum and boron.

The method disclosed in this specification manufactures a switching device. The switching device includes a semiconductor substrate, a trench formed on an upper surface of the semiconductor substrate, a gate insulating film covering an inner surface of the trench, and a gate electrode located within the trench. The semiconductor substrate includes first to fourth semiconductor regions. The first semiconductor region is of n-type and in contact with the insulating film on a side surface of the trench. The second semiconductor region is of p-type, positioned under the first semiconductor region, and in contact with the insulating film on the side surface of the trench. The third semiconductor region is of n-type, positioned under the second semiconductor region, and in contact with the insulating film on the side surface of the trench. The fourth semiconductor region is of p-type, positioned in a range deeper than the second semiconductor region, consecutive with the second semiconductor region, and facing the gate insulating film via the third semiconductor region. The method includes forming the second semiconductor region in which aluminum is doped, and implanting boron into a range in the semiconductor substrate in which the fourth semiconductor region is to be formed. Hereinafter, this method is referred to as the first method.

Moreover, the second semiconductor region in which aluminum is doped may be formed by implanting aluminum to the semiconductor substrate or by epitaxial growth. In addition, whichever of the forming of the second semiconductor region and the forming of the fourth semiconductor region may be performed first. In addition, in the present specification, the term “a range in which a predetermined region (for example, any of the first to fifth semiconductor regions) is to be formed” means to a range in which the region is to be subsequently formed.

With the first manufacturing method, since the fourth semiconductor region (a region corresponding to a deep region) is formed by implanting boron into a range in which the fourth semiconductor region is to be formed, a width of the fourth semiconductor region can be reduced. In addition, according to the manufacturing method, the second semiconductor region (a region corresponding to a base region) doped with aluminum is formed. Therefore, a density of p-type impurities of the second semiconductor region can be increased. As a result, according to the manufacturing method, a concentration of an electric field on the gate insulating film can be suppressed. Thus, this manufacturing method can manufacture a switching device having a high avalanche endurance and a small size.

Further, this specification discloses a novel switching device. The switching device includes a semiconductor substrate, a trench formed on an upper surface of the semiconductor substrate, a gate insulating film covering an inner surface of the trench, and a gate electrode located within the trench. The semiconductor substrate includes first-fourth semiconductor regions. The first semiconductor region is of n-type and in contact with the insulating film. The second semiconductor region is of p-type, positioned under the first semiconductor region, and in contact with the insulating film. The third semiconductor region is of n-type, positioned under the second semiconductor region, and in contact with the insulating film. The fourth semiconductor region is of p-type, positioned in a range deeper than the second semiconductor region, consecutive with the second semiconductor region, and facing the gate insulating film via the third semiconductor region. A density of aluminum is higher than a density of boron in at least a part of the second semiconductor region. The density of the boron is higher than the density of the aluminum in the fourth semiconductor region.

The switching device can be manufactured by the first manufacturing method described above. As a result, the switching device is capable of suppressing a concentration of an electric field on the gate insulating film, and has a high avalanche resistance and a small size.

### BRIEF DESCRIPTION OF DRAWINGS

FIG. 1 is a longitudinal sectional view of a MOSFET 10.

FIG. 2 is a ,graph showing a distribution of a density of impurities in a semiconductor substrate 12 when viewed along line A-A in FIG. 1.

FIG. 3 is a graph showing a distribution of the density of impurities in the semiconductor substrate 12 when viewed along line B-B in FIG. 1.

FIG. 4 is a graph showing a distribution of the density of impurities in the semiconductor substrate 12 when viewed along line C-C in FIG. 1.

FIG. 5 is a flow chart showing a manufacturing process of the MOSFET 10.

FIG. 6 is a longitudinal sectional view of a semiconductor substrate 100 after step S4 is performed.

FIG. 7 is an explanatory diagram of boron implantation in step S6.

FIG. 8 is an explanatory diagram of a tilt angle θ1.

FIG. 9 is an explanatory diagram of aluminum implantation in step S8.

FIG. 10 is an explanatory diagram of nitrogen implantation in step S10.

FIG. 11 is an explanatory diagram of nitrogen implantation in step S12.

FIG. 12 is a longitudinal sectional view of the semiconductor substrate 100 after step S14 is performed.

FIG. 13 is a graph showing a distribution of a density of boron in a depth direction for each tilt angle upon boron implantation.

FIG. 14 is a graph showing a distribution of a density of impurities in the semiconductor substrate 12 when viewed along line A-A of a MOSFET according to a second embodiment.

FIG. 15 is an explanatory diagram of boron implantation in step S6 according to the second embodiment.

FIG. 16 is a graph showing a distribution of a density of impurities in the semiconductor substrate 12 when viewed along line A-A of a MOSFET according to a modification.

FIG. 17 is a graph showing a distribution of a density of impurities in the semiconductor substrate 12 when viewed along line B-B of a MOSFET according to a comparative example.

FIG. 18 is an explanatory diagram of boron implantation in step S6 according to a third embodiment.

FIG. 19 is a graph showing a distribution of a density of boron in a depth direction for each tilt angle upon boron implantation in a case where the boron is implanted through a silicon oxide film.

FIG. 20 is a graph showing a relationship between a thickness of a silicon oxide film and ΔNp.

FIG. 21 is an explanatory diagram of boron implantation in step S6 according to a fourth embodiment.

### DETAILED DESCRIPTION

In one aspect of the above mentioned first method, in the implanting, boron may be irradiated toward the upper surface of the semiconductor substrate in a state where a mask having an opening is set on the upper surface of the semiconductor substrate. In the implanting, boron having passed through the opening may be implanted into the range in which the fourth semiconductor region is to be formed, and boron having penetrated the mask may be implanted into a range corresponding to the second semiconductor region. Hereinafter, this method is referred to as the second method.

In the present specification, the term “a range corresponding to a predetermined region (for example, any of the first to fifth semiconductor regions or an insulating film)” means either a range in which the region is to be subsequently formed or a range in which the region is already formed. For example, the description “boron is implanted into a range corresponding to the second semiconductor region” above may be interpreted as boron being implanted into the second semiconductor region that is already formed or as boron being implanted into a region in which the second semiconductor region is not yet formed but is to be subsequently formed.

In the second manufacturing method, boron is also implanted into the second semiconductor region. Even when boron is implanted into the second semiconductor region, characteristics of the switching device are hardly affected. In addition, since boron can be implanted with low energy, a thickness of an ion implantation mask can be reduced. As a result, the mask can be formed with high accuracy. In other words, the opening can be formed with high accuracy. Therefore, the fourth semiconductor region can be formed with higher accuracy (in other words, in a smaller size) and, in turn, the switching device can be further downsized.

Regarding the above mentioned second method, in the implanting, boron may be implanted so that an average of depths at which boron having penetrated the mask stops in the semiconductor substrate is within the range corresponding to the second semiconductor region. Hereinafter, this method is referred to as the third method.

The above mentioned second or third method may further include forming a fifth semiconductor region by irradiating p-type impurities toward the upper surface of the semiconductor substrate in the state where the same mask as that used in the implanting is set on the upper surface of the semiconductor substrate. The fifth semiconductor region may be exposed at the upper surface of the semiconductor substrate, may be consecutive with the second semiconductor region, and may have a higher density of the p-type impurities than that in the second semiconductor region.

According to such a configuration, the fifth semiconductor region can be efficiently formed.

Any of the above mentioned methods may further include implanting n-type impurities into a specific range between the range corresponding to the fourth semiconductor region and a range corresponding to the gate insulating film. Hereinafter, this method is referred to as the fourth method.

According to the fourth manufacturing method, the width of the fourth semiconductor region can be further reduced.

Regarding the fourth method, in the implanting the n-type impurities into the specific range, the n-type impurities may be irradiated toward the upper surface of the semiconductor substrate in a state where a mask having an opening is set on the upper surface of the semiconductor substrate. The n-type impurities having passed through the opening may be implanted into the specific range. The method may further include irradiating the n-type impurities toward the upper surface of the semiconductor substrate in the state where the same mask as that used in the implanting the n-type impurities into the specific range is set on the upper surface of the semiconductor substrate. Wherein the n-type impurities having passed through the opening may be implanted into a range in which the first semiconductor region is to be formed.

According to such a configuration, the first semiconductor region can be efficiently formed.

Regarding any of the above mentioned methods, the semiconductor substrate may be made of SiC. In the implanting, boron implanted at a tilt angle with respect to a (0001) plane or a (000-1) plane of the semiconductor substrate.

This constitution may be able to suppress an occurrence of channeling during implanting boron. In this constitution, the tilt angle may be equal to or more than 2 degrees and equal to or less than 8 degrees.

Furthermore, regarding the first method, in the implanting, boron may be irradiated toward the upper surface of the semiconductor substrate in a state where a mask having an opening is set on the upper surface of the semiconductor substrate and an oxide silicon film is located on the upper surface of the semiconductor substrate within the opening. Boron having penetrated the oxide silicon may be implanted into the range in which the fourth semiconductor region is to be formed.

When boron having penetrated the oxide silicon is implanted in the above mentioned manner, an occurrence of channeling during implanting boron may be suppressed. In this constitution, a thickness of the oxide silicon may be equal to or more than 100 nm.

Regarding the first method, in the implanting, boron may be irradiated toward the upper surface of the semiconductor substrate in a state where a mask having an opening is set on the upper surface of the semiconductor substrate. Boron having passed through the opening may be implanted into the range in which the fourth semiconductor region is to be formed.

By adopting a metallic mask in this manner, boron can be shut out using a thin mask. A thin mask can be formed with high accuracy. Therefore, the use of such a mask enables the fourth semiconductor region to be formed with high accuracy. Therefore, a width of the fourth semiconductor region can be further reduced.

In one aspect of the above mentioned switching device, aluminum and boron may be doped in the second semiconductor region.

The switching device can be manufactured by the second manufacturing method described above. Therefore, a width of the fourth semiconductor region can be further reduced.

Regarding the above mentioned switching device having the second semiconductor region in which boron is doped, a peak value of a density of boron in a distribution of the density of boron along a depth direction in the first, second, and third semiconductor regions may be within the second semiconductor region.

The switching device can be manufactured by the third manufacturing method described above.

Regarding any of the above mentioned switching devices, a density of the n-type impurities may be higher in a specific range between the fourth semiconductor region and the gate insulating film than in a range outside the specific range and in the third semiconductor region being in contact with the specific range.

The switching device can be manufactured by the fourth manufacturing method described above. Therefore, a width of the fourth semiconductor region can be further reduced.

Regarding any of the above mentioned switching devices, the density of aluminum at a position which is in a vicinity of a border of the second semiconductor region and the fourth semiconductor region may be equal to or less than one-tenth of a peak value of the density of aluminum in the second semiconductor region. The position may be where the density of aluminum and the density of boron are identical to each other.

According to such a configuration, a density of impurities in a vicinity of the border can be prevented from increasing excessively. As a result, formation of crystal defects in the vicinity of the border can be suppressed and an occurrence of a leakage current in the vicinity of the border can be suppressed.

### First Embodiment

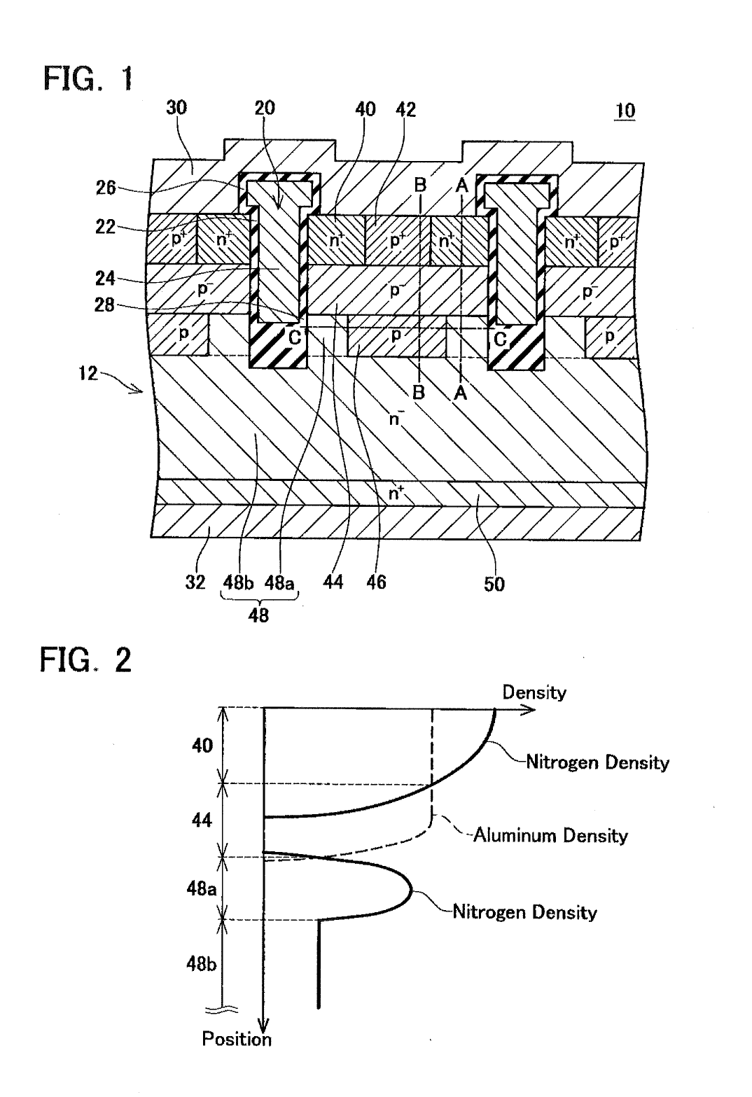

As shown in FIG. 1, a MOSFET 10 according to the first embodiment includes a semiconductor substrate 12, and electrodes and insulating films formed on an upper surface and the like of the semiconductor substrate 12. The semiconductor substrate 12 is a SiC substrate.

A plurality of trenches 20 is formed on the upper surface of the semiconductor substrate 12. In the explanation herein, since the plurality of trenches have similar configuration, one trench 20 and its relevant structure will mainly be explained. An inner surface of the trench 20 is covered by a gate insulating film 22. A gate electrode 24 is formed within the trench 20. The gate electrode 24 is insulated from the semiconductor substrate 12 by the gate insulating film 22. The gate insulating film 22 under the gate electrode 24 is formed thicker than the gate insulating film 22 located to a side of the gate electrode 24. A part of the gate electrode 24 is positioned above the trench 20. The gate electrode 24 above the trench 20 is covered by an interlayer insulating film 26.

A source electrode 30 is formed on the upper surface of the semiconductor substrate 12. The source electrode 30 is insulated from the gate electrode 24 by the interlayer insulating film 26. A drain electrode 32 is formed on a lower surface of the semiconductor substrate 12.

A source region 40, a contact region 42, a base region 44, a deep region 46, a drift region 48, and a drain region 50 are formed inside the semiconductor substrate 12.

The source region 40 is an n-type region. The source region 40 is formed in a range exposed at the upper surface of the semiconductor substrate 12. The source region 40 is in contact with the gate insulating film 22. The source region 40 is ohmically connected to the source electrode 30.

The contact region 42 is a p-type region. The contact region 42 is formed in a range exposed at the upper surface of the semiconductor substrate 12 (a range between two source regions 40). The contact region 42 is ohmically connected to the source electrode 30.

The base region 44 is a p-type region that is consecutive with the contact region 42. A density of p-type impurities is lower in the base region 44 than in the contact region 42. The base region 44 is formed under the source region 40 and the contact region 42. The base region 44 is in contact with the gate insulating film 22 under the source region 40.

The deep region 46 is a p-type region that is consecutive with the base region 44. A density of p-type impurities is lower in the deep region 46 than in the contact region 42. The deep region 46 is formed under the base region 44. The n-type drift region 48 (more specifically, a high-density drift region 48a to be described later) exists between the deep region 46 and the gate insulating film 22. Therefore, the deep region 46 is not in contact with the gate insulating film 22 and faces the gate insulating film 22 via the drift region 48.

The drift region 48 is an n-type region. A density of n-type impurities is lower in the drift region 48 than in the source region 40. The drift region 48 is formed under the base region 44 and the deep region 46. The drift region 48 is separated from the source region 40 by the base region 44. The drift region 48 is in contact with the gate insulating film 22 formed on a side surface of the trench 20 and with the gate insulating film 22 formed on a bottom portion of the trench 20. The drift region 48 includes a high-density drift region 48a and a low-density drift region 48b. The high-density drift region 48a is formed between the deep region 46 and the gate insulating film 22. The low-density drift region 48b is formed at a deeper position than the high-density drift region 48a. A density of n-type impurities is higher in the high-density drift region 48a than in the low-density drift region 48b.

The drain region 50 is an n-type region. The drain region 50 is formed under the drift region 48. A density of n-type impurities is higher in the drain region 50 than in the drift region 48. The drain region 50 is formed in a range exposed at the lower surface of the semiconductor substrate 12. The drain region 50 is ohmically connected to the drain electrode 32.

FIG. 2 shows a distribution of a density of impurities in the semiconductor substrate 12 when viewed along line A-A in FIG. 1. As shown in FIG. 2, in the source region 40 and the base region 44, aluminum that is a p-type impurity is distributed at an approximately constant density. Nitrogen (n-type impurity) exists in the source region 40 at a higher density than aluminum. Although there are hardly any p-type impurities in the drift region 48, nitrogen (n-type impurity) exists in the drift region 48. A density of nitrogen in the high-density drift region 48a is higher than a density of nitrogen in the low-density drift region 48b.

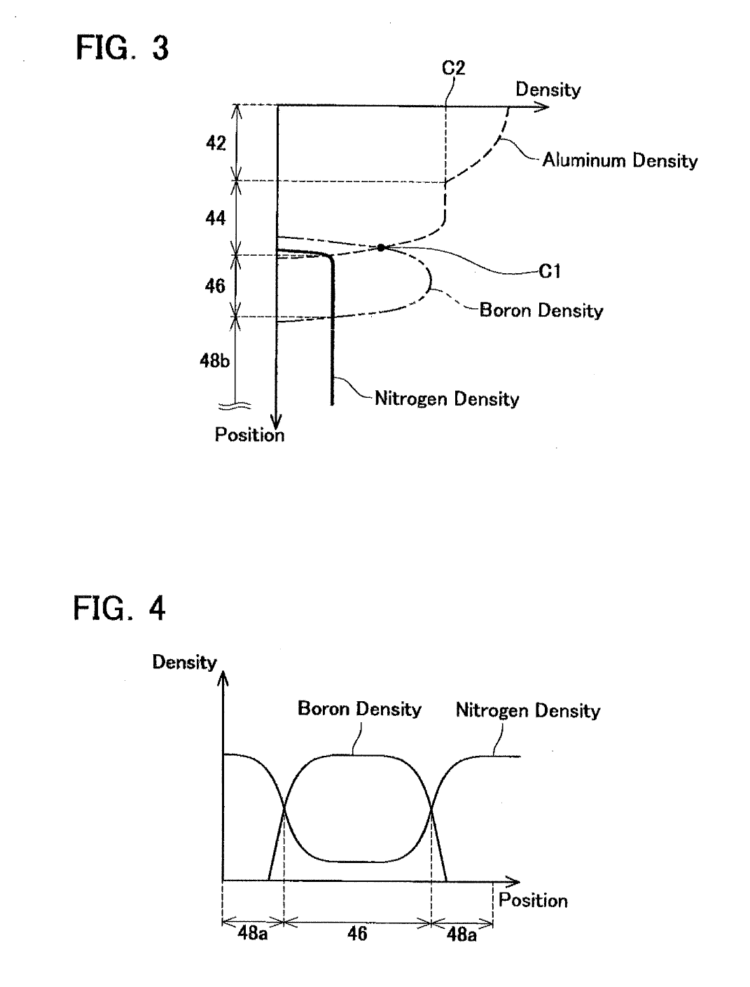

FIG. 3 shows a distribution of a density of impurities in the semiconductor substrate 12 when viewed along line B-B in FIG. 1. As shown in FIG. 3, even in the base region 44 at a position of the line B-B (in other words, the base region 44 under the contact region 42), aluminum that is a p-type impurity is distributed at an approximately constant density. A density of aluminum is higher in the contact region 42 than in the base region 44. Although there is hardly any aluminum in the deep region 46, boron (p-type impurity) exists at a high density in the deep region 46. Nitrogen exists at a low density in the deep region 46 and in the low-density drift region 48b.

FIG. 4 shows a distribution of a density of impurities in the semiconductor substrate 12 when viewed along line C-C in FIG. 1. As shown in FIG. 4, a density of nitrogen (n-type impurity) is higher in the high-density drift region 48a on both sides of the deep region 46 and lower in the deep region 46. In addition, as described earlier, boron (p-type impurity) exists at a high density in the deep region 46.

Next, operations of the MOSFET 10 will be described. When turning on the MOSFET 10, a predetermined voltage is applied to the gate electrode 24 in a state where a forward voltage is applied between the source electrode 30 and the drain electrode 32. As a result, a channel is formed in the base region 44 in a range that is in contact with the gate insulating film 22. Accordingly, electrons flow from the source electrode 30 to the drain electrode 32 though the source region 40, the channel, the drift region 48, and the drain region 50.

In addition, when the MOSFET 10 is turned off, a strong electric field is generated within the semiconductor substrate 12. In particular, a high electric field is likely to be applied to the gate insulating film 22 in a vicinity of a bottom portion of the trench 20 (the gate insulating film 22 in contact with the drift region 48). Among the gate insulating film 22 formed on a side surface of the gate electrode 24, the gate insulating film 22 at a location 28 that is in contact with the drift region 48 is thin. Therefore, when a high electric field such as described above is applied to the gate insulating film 22 at the location 28, a dielectric breakdown of the gate insulating film 22 may occur. However, with the MOSFET 10, a depletion layer spreads from the deep region 46 to the high-density drift region 48a when the MOSFET 10 is in off state. Due to the depletion layer, the electric field applied to the gate insulating film 22 at the location 28 is reduced. Therefore, a dielectric breakdown of the gate insulating film 22 is less likely to occur. Consequently, the MOSFET 10 has high withstand voltage characteristics.

In addition, when the MOSFET 10 is in off state, a high electric field may be generated locally within the drift region 48 to cause an avalanche phenomenon within the drift region 48. In the MOSFET 10, as shown in FIGS. 2 and 3, since the p-type impurities doped in the base region 44 is aluminum, a density of carriers in the base region 44 is relatively high. Therefore, holes created within the drift region 48 due to the avalanche phenomenon flow into the base region 44 in a short period of time. As described above, since holes created by the avalanche phenomenon are discharged from the drift region 48 in a short period of time, an increase in an avalanche current is suppressed. In other words, the MOSFET 10 has high avalanche endurance.

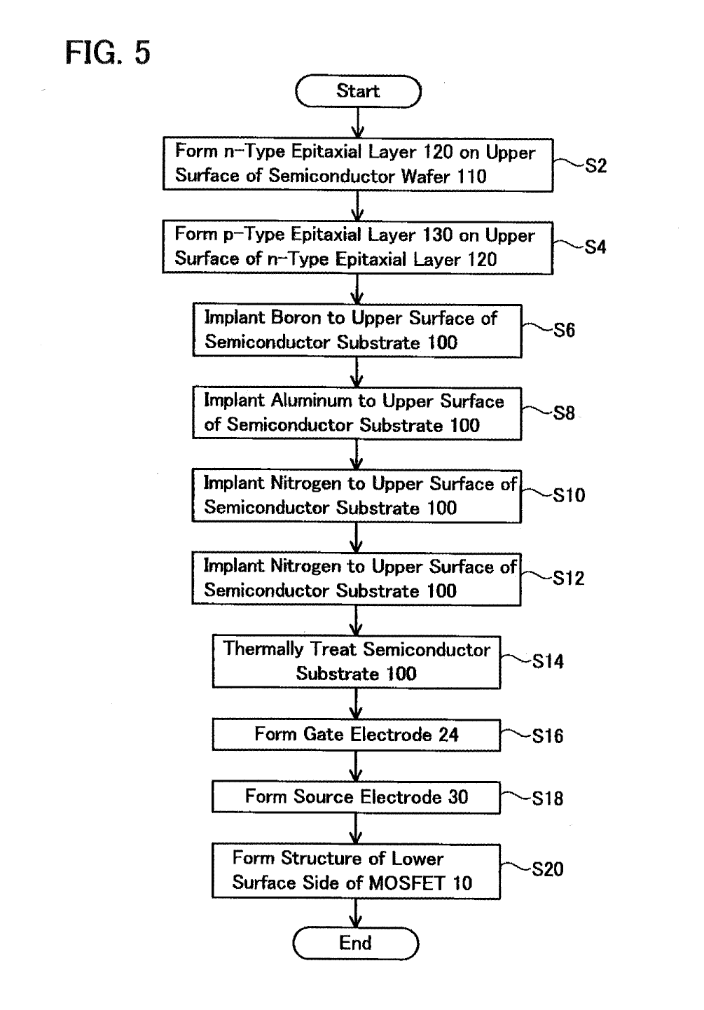

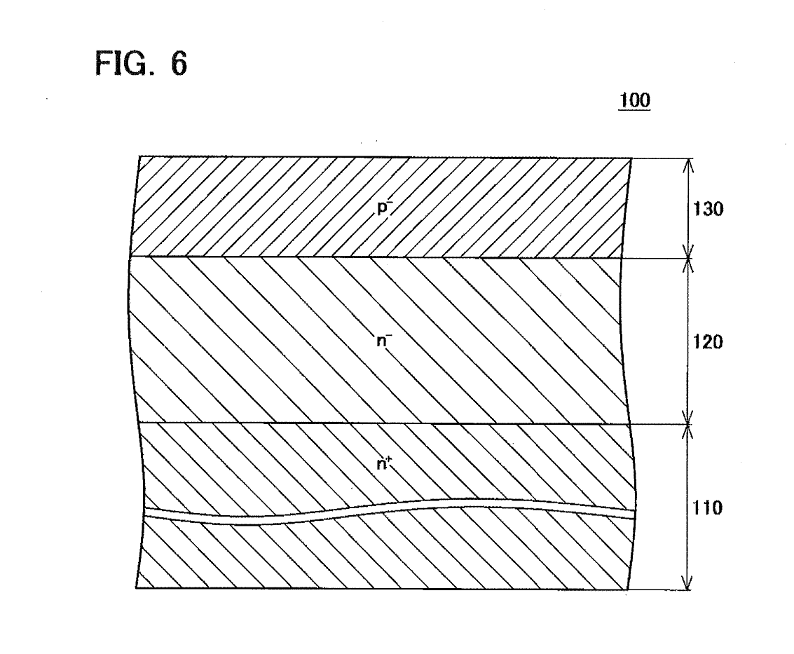

Next, a method for manufacturing the MOSFET 10 will be described. In this manufacturing method, the MOSFET 10 is manufactured from a semiconductor wafer (a semiconductor wafer 110 shown in FIG. 6) which is made of 4H-SiC and in which an upper surface is a (0001) plane or a (000-1) plane. The semiconductor wafer 110 is of n-type and has an approximately same density of n-type impurities as the drain region 50. The MOSFET 10 is manufactured by the processes illustrated in a flow chart shown in FIG. 5.

In step S2, an n-type epitaxial layer 120 shown in FIG. 6 is grown on the upper surface of the semiconductor wafer 110. In this case, the n-type epitaxial layer 120 is grown with a thickness of approximately 13 μm and a density of n-type impurities (nitrogen) of approximately 1×10¹⁵ cm⁻³. The density of n-type impurities is equivalent to the density of n-type impurities of the low-density drift region 48b.

In step S4, a p-type epitaxial layer 130 shown in FIG. 6 is grown on an upper surface of the n-type epitaxial layer 120. In this case, the p-type epitaxial layer 130 is grown with a thickness of approximately 1.8 μm and a density of p-type impurities (aluminum) of approximately 5×10¹⁷ cm ⁻³. The density of p-type impurities is equivalent to the density of p-type impurities of the base region 44. Accordingly, as shown in FIG. 6, the semiconductor substrate 100 including three layers, namely, the semiconductor wafer 110, the n-type epitaxial layer 120, and the p-type epitaxial layer 130 is obtained.

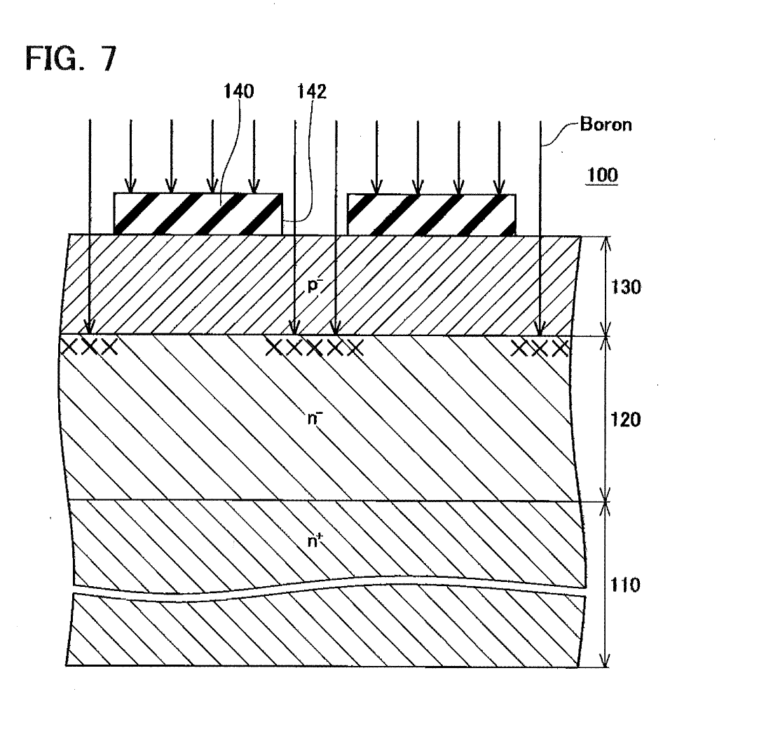

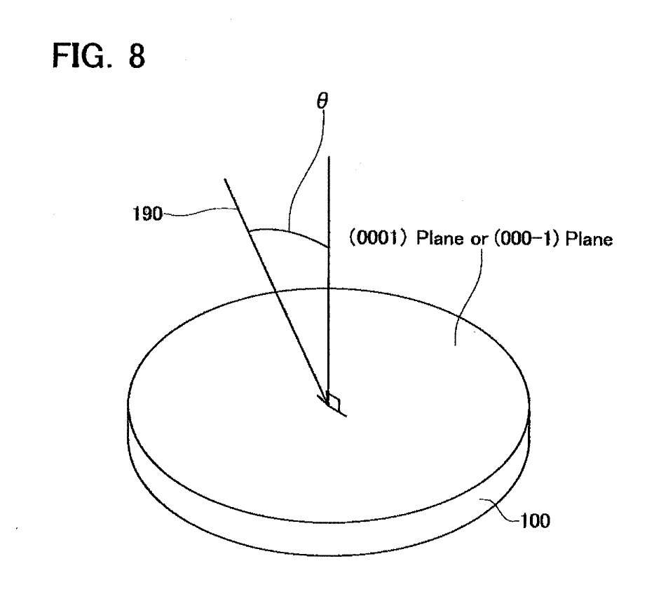

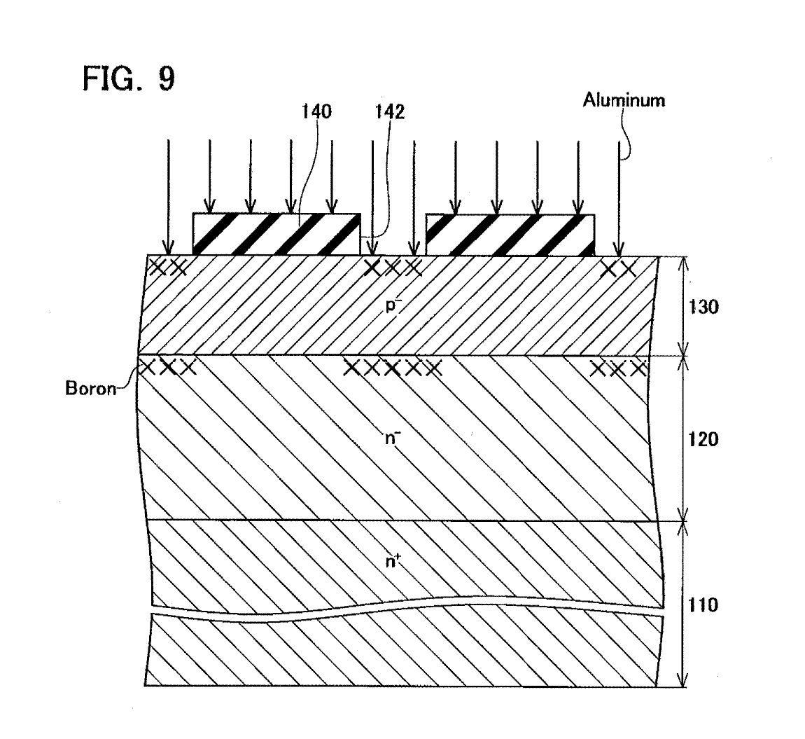

In step S6, a mask 140 is formed on the upper surface of the semiconductor substrate 100 as shown in FIG. 7. In this case, the mask 140 is formed so that an opening 142 is positioned on a range in which the contact region 42 is to be formed. Once the mask 140 is formed, boron is irradiated toward the upper surface of the semiconductor substrate 100. As shown in FIG. 8, a tilt angle θ1 is provided between an irradiating direction 190 of boron and a perpendicular of the upper surface of the semiconductor substrate 100 (in other words, the (0001) plane or the (000-1) plane of the semiconductor substrate 100). In doing so, the tilt angle θ1 is adjusted so as to be equal to or more than 2 degrees and equal to or less than 8 degrees. In addition, boron is irradiated by adjusting energy so that the boron irradiated toward the mask 140 stops inside the mask 140. Therefore, as shown in FIG. 7, boron is not implanted into the semiconductor substrate 100 in a range that is covered by the mask 140. On the other hand, boron having passed through the opening 142 is implanted into the semiconductor substrate 100 in a range in which the opening 142 is formed. In this case, boron is irradiated so that the boron having passed through the opening 142 stops within the n-type epitaxial layer 120 in a vicinity of the p-type epitaxial layer 130 (at a depth of approximately 2.2 μm from the upper surface of the semiconductor substrate 100). In other words, boron is implanted into the range in which the deep region 46 is to be formed.

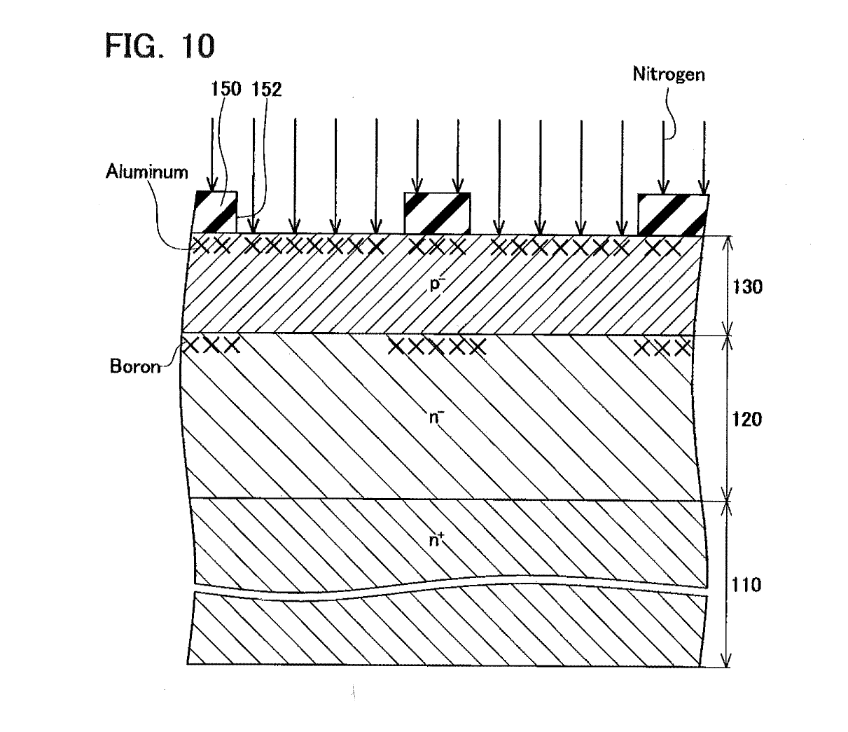

In step S8, aluminum is irradiated toward the upper surface of the semiconductor substrate 100 in the state where the mask 140 (the mask used in step S6) is located on the upper surface of the semiconductor substrate 100. In this case, aluminum is irradiated by adjusting energy so that the aluminum irradiated toward the mask 140 stops inside the mask 140. Therefore, as shown in FIG. 9, aluminum is not implanted into the semiconductor substrate 100 in a range that is covered by the mask 140. On the other hand, aluminum having passed through the opening 142 is implanted into the semiconductor substrate 100 in a range in which the opening 142 is formed. Aluminum is implanted so that the aluminum having passed through the opening 142 stops in a vicinity of the upper surface of the semiconductor substrate 100. In other words, aluminum is implanted into the range in which the contact region 42 is to be formed. The mask 140 is removed after step S8 is completed.

In step S10, a mask 150 is formed on the upper surface of the semiconductor substrate 100 as shown in FIG. 10. In this case, the mask 150 is formed so that an opening 152 is positioned on a range in which the source region 40 is to be formed. Once the mask 150 is formed, nitrogen is irradiated toward the upper surface of the semiconductor substrate 100. In this case, nitrogen is irradiated by adjusting energy so that the nitrogen irradiated toward the mask 150 stops inside the mask 150. Therefore, nitrogen is not implanted into the semiconductor substrate 100 in a range that is covered by the mask 150. On the other hand, nitrogen having passed through the opening 152 is implanted into the semiconductor substrate 100 in a range in which the opening 152 is formed. Nitrogen is implanted so that the nitrogen having passed through the opening 152 stops in a vicinity of the upper surface of the semiconductor substrate 100. In other words, nitrogen is implanted into the range in which the source region 40 is to be formed.

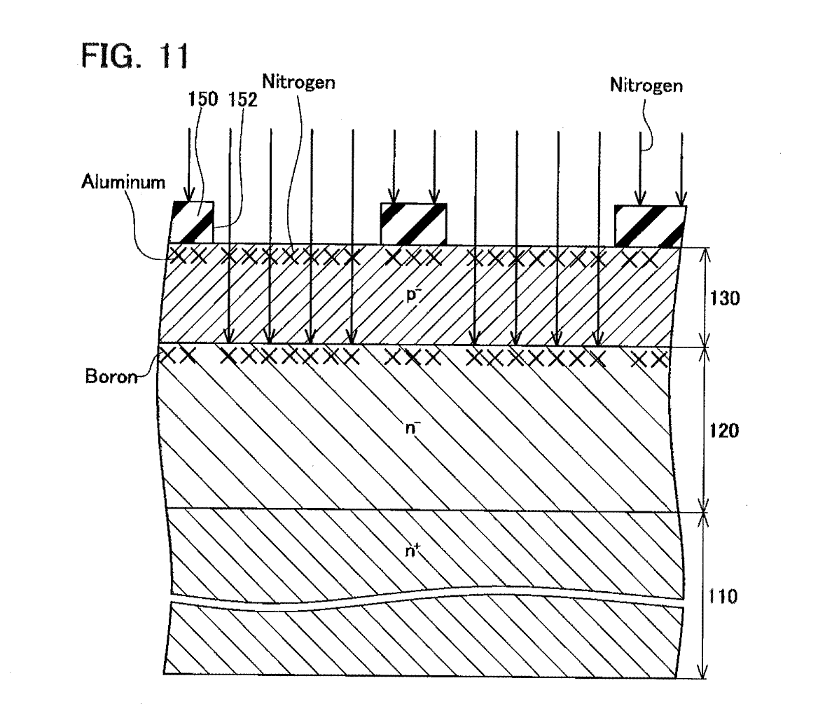

In step S12, as shown in FIG. 11, nitrogen is irradiated toward the upper surface of the semiconductor substrate 100 in a state where the mask 150 (the mask used in step S10) is located on the upper surface of the semiconductor substrate 100. In this case, nitrogen is irradiated by adjusting energy so that the nitrogen irradiated toward the mask 150 stops inside the mask 150. Therefore, nitrogen is not implanted into the semiconductor substrate 100 in a range that is covered by the mask 150. On the other hand, nitrogen having passed through the opening 152 is implanted into the semiconductor substrate 100 in a range in which the opening 152 is formed. Nitrogen is implanted so that the nitrogen having passed through the opening 152 stops within the n-type epitaxial layer 120 in a vicinity of the p-type epitaxial layer 130. In other words, nitrogen is implanted into a range in which the high-density drift region 48a is to be formed. The mask 150 is removed after step S12 is completed.

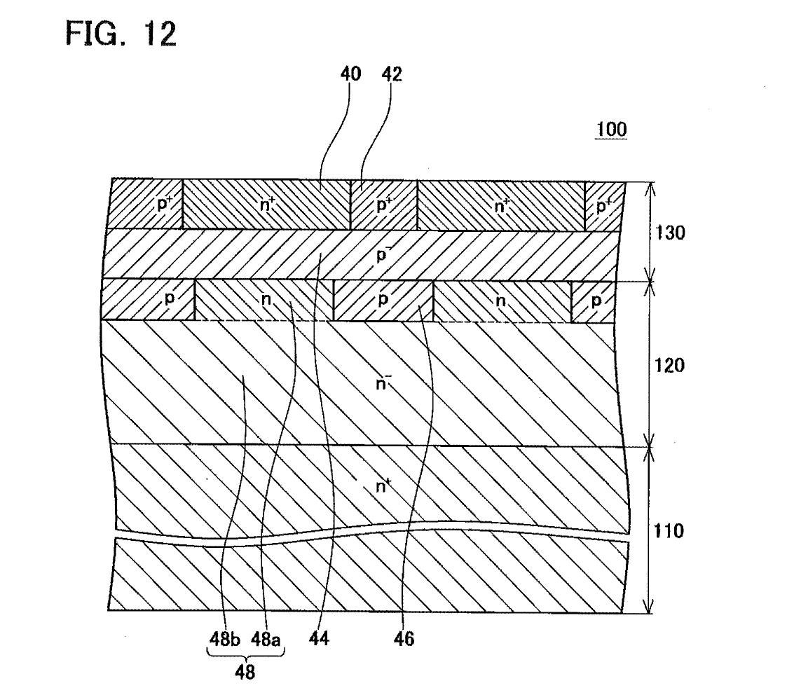

In step S14, the semiconductor substrate 100 is thermally treated. Accordingly, the impurities implanted in steps S6 to S12 are diffused and activated. As a result, as shown in FIG. 12, the source region 40, the contact region 42, the deep region 46, and the high-density drift region 48a are formed within the semiconductor substrate 100. A region in the p-type epitaxial layer 130 that did not become the source region 40 and the contact region 42 becomes the base region 44. In addition, a region in the n-type epitaxial layer 120 that did not become the high-density drift region 48a and the deep region 46 becomes the low-density drift region 48b.

In step S16, the gate electrode 24 is formed by the following processes. First, the trenches 20 are formed on the upper surface of the semiconductor substrate 100 by dry etching. Next, silicon oxide (BPSG, NSG, LTO, or the like) is formed on the surface of the semiconductor substrate 100 by CVD. Accordingly, silicon oxide is filled into the trenches 20. The grown silicon oxide is then etched. In this case, silicon oxide with a thickness of approximately 1 μm (a gate insulating film in a lower part of the gate electrode 24 shown in FIG. 1) is left in a bottom portion of the trenches 20. Next, a silicon oxide film with a thickness of approximately 100 nm is formed on a side surface of the trenches 20 by sacrificial oxidation, CVD, or the like. The silicon oxide in the bottom portion of the trenches 20 and the silicon oxide film on the side surface of the trenches 20 form the gate insulating film 22 shown in FIG. 1. Next, the gate electrode 24 is formed by growing polysilicon in the trenches 20. The interlayer insulating film 26 is then formed by sacrificial oxidation, CVD, or the like.

In step S18, the source electrode 30 is formed by sputtering or the like. Accordingly, a structure on the upper surface side of the MOSFET 10 shown in FIG. 1 is completed.

In step S20, a structure on a lower surface side of the MOSFET 10 is formed by the following processes. First, the lower surface of the semiconductor substrate 100 is polished to make the semiconductor substrate 100 thinner. Next, the drain electrode 32 is formed by sputtering or the like. Accordingly, the MOSFET 10 shown in FIG. 1 is completed.

In the MOSFET 10 manufactured by the manufacturing method described above, the base region 44 is constituted by the p-type epitaxial layer 130 doped with aluminum. As a result, the base region 44 with a high density of carriers is formed. Therefore, according to this manufacturing method, the MOSFET 10 with a high avalanche resistance can be manufactured.

In addition, according to the manufacturing method described above, the deep region 46 is formed by implanting boron into the semiconductor substrate 100. Since boron can be implanted into the semiconductor substrate 100 at a low energy, an implantation range of boron can be accurately controlled. Therefore, a fine deep region 46 can be formed while keeping diffusion of boron in the semiconductor substrate 100 to a low level. In particular, with this manufacturing method, n-type impurities are implanted in step S12 into a region adjacent to the deep region 46. Therefore, as shown in FIG. 4, the high-density drift region 48a with a high density of n-type impurities is formed in a range adjacent to the deep region 46. A width of the deep region 46 can be further reduced by the high-density drift region 48a. In addition, when the region between the gate insulating film 22 and the deep region 46 has a high density of n-type impurities in this manner, even if an error occurs in a density or an implantation range of boron implanted toward the deep region 46, the gate insulating film 22 and the deep region 46 can be prevented from coming into contact with each other. Therefore, an interval between the gate insulating film 22 and the deep region 46 can be reduced. In this manner, according to the manufacturing method described above, the width of the deep region 46 and an interval between the gate insulating film 22 and the deep region 46 can be reduced. Therefore, according to this manufacturing method, a small MOSFET 10 can be manufactured.

Furthermore, boron can be implanted into the semiconductor substrate with a lower energy than aluminum. Therefore, by forming the deep region 46 by implanting boron as is the case of the manufacturing method described above, an amount of crystal defects created in the semiconductor substrate 100 can be suppressed in comparison to a case in which a deep region is formed by implanting aluminum. Consequently, according to this manufacturing method, the MOSFET 10 that is less likely to create a leakage current can be manufactured.

Moreover, according to the manufacturing method described above, step S8 (implantation of aluminum into the contact region 42) is performed in a state where the same mask as that used in step S6 (implantation of boron into the deep region 46) is set on the upper surface of the semiconductor substrate 100. Since ion implantation into two regions can be performed using a single mask, the MOSFET 10 can be manufactured efficiently with this manufacturing method.

In addition, according to the manufacturing method described above, step S12 (implantation of n-type impurities into the high-density drift region 48a) is performed in a state where the same mask as that used in step S10 (implantation of n-type impurities into the source region 40) is set on the upper surface of the semiconductor substrate 100. Since ion implantation into two regions can be performed using a single mask, the MOSFET 10 can be manufactured efficiently with this manufacturing method.

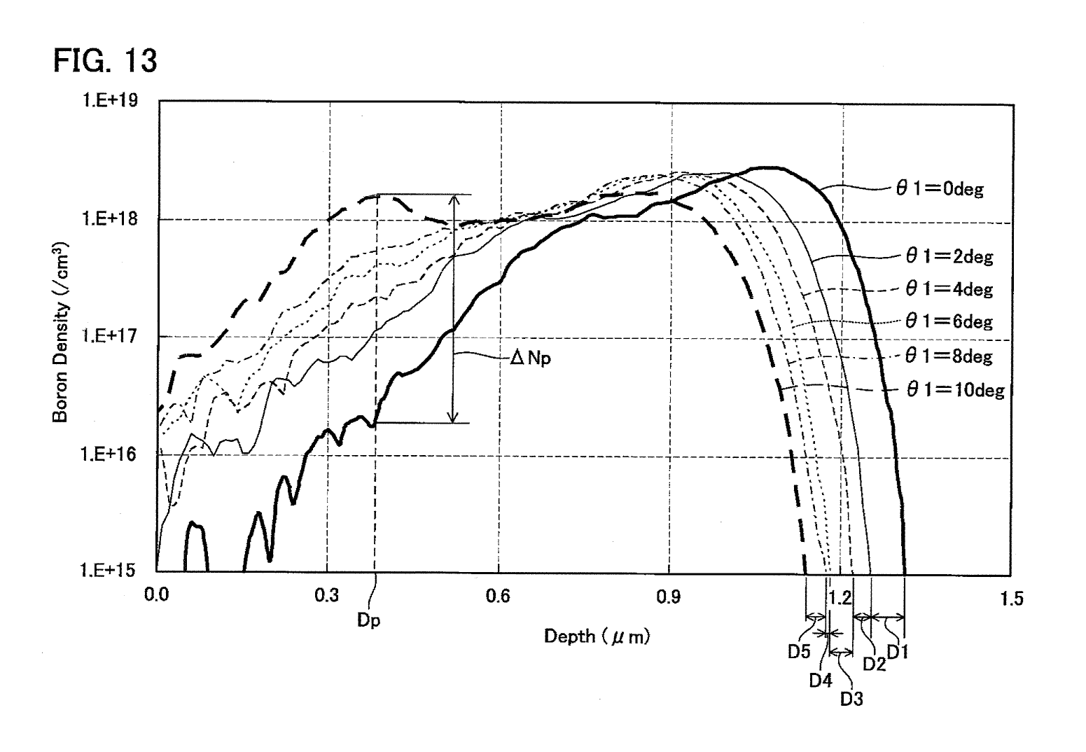

Furthermore, according to the manufacturing method described above, the tilt angle θ1 is set equal to or more than 2 degrees and equal to or less than 8 degrees when implanting boron in step S6. FIG. 13 shows a distribution of a density of boron in a depth direction of a semiconductor substrate made of SiC when boron is implanted into the semiconductor substrate. FIG. 13 shows a distribution of a density of boron for each tilt angle θ1 upon boron implantation. Values D1 to D5 in FIG. 13 represent a difference in a position of a deepest part of a boron implantation range among respective graphs. As shown, the value D1 is significantly greater than the values D2 to D5. In other words, when the tilt angle θ1 is 0 degrees, an implantation depth of boron becomes significantly deeper compared to a case where the tilt angle θ1 is 2 degrees or more. Therefore, in order to suppress a variance in the implantation depth of boron due to an error in the tilt angle θ1, the tilt angle θ1 is favorably 2 degrees or more. In addition, two peaks of boron density is formed when the tilt angle θ1 is 10 degrees. In other words, a second peak of boron density is formed at a position indicated by a depth Dp. In order to prevent such a second peak from being created, the tilt angle θ1 is favorably 8 degrees or less. According to the manufacturing method described above, since the tilt angle is equal to or more than 2 degrees and equal to or less than 8 degrees, a distribution of the density of boron after implantation can be accurately controlled and the deep region 46 can be accurately formed.

Moreover, according to the manufacturing method described above, the high-density drift region 48a is formed under the base region 44. Accordingly, an electric resistance of the drift region 48 adjacent to the channel is small and loss created in the MOSFET 10 is reduced.

### Second Embodiment

Next, a MOSFET and a method for manufacturing the same according to a second embodiment will be described. The MOSFET according to the second embodiment has a similar cross sectional structure to the MOSFET 10 according to the first embodiment shown in FIG. 1. However, a distribution of a density of impurities in the MOSFET according to the second embodiment when viewed along line A-A in FIG. 1 differs from the distribution of the density of impurities of the MOSFET 10 according to the first embodiment shown in FIG. 2. On the other hand, distributions of the density of impurities in the MOSFET according to the second embodiment when viewed along lines B-B and C-C in FIG. 1 are the same as the distributions of the density of impurities of the MOSFET 10 according to the first embodiment shown in FIGS. 3 and 4.

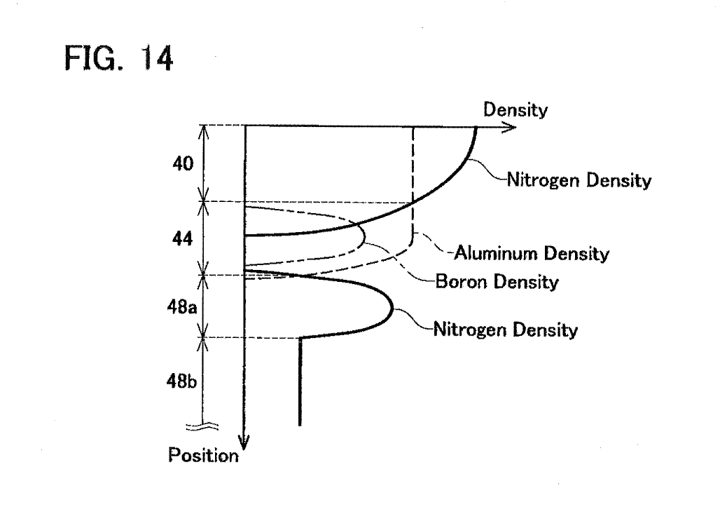

FIG. 14 shows a distribution of a density of impurities in the MOSFET according to the second embodiment when viewed along line A-A in FIG. 1. As shown in FIG. 14, in the MOSFET according to the second embodiment, boron exists within the base region 44. A peak value of a density of boron is located approximately at center in a depth direction of the base region 44. The peak value of the density of boron in the base region 44 is lower than a density of aluminum in the base region 44. As shown, even when boron exists in the base region 44, characteristics of the MOSFET is hardly affected. In other words, the MOSFET according to the second embodiment operates approximately in a same manner as the MOSFET 10 according to the first embodiment.

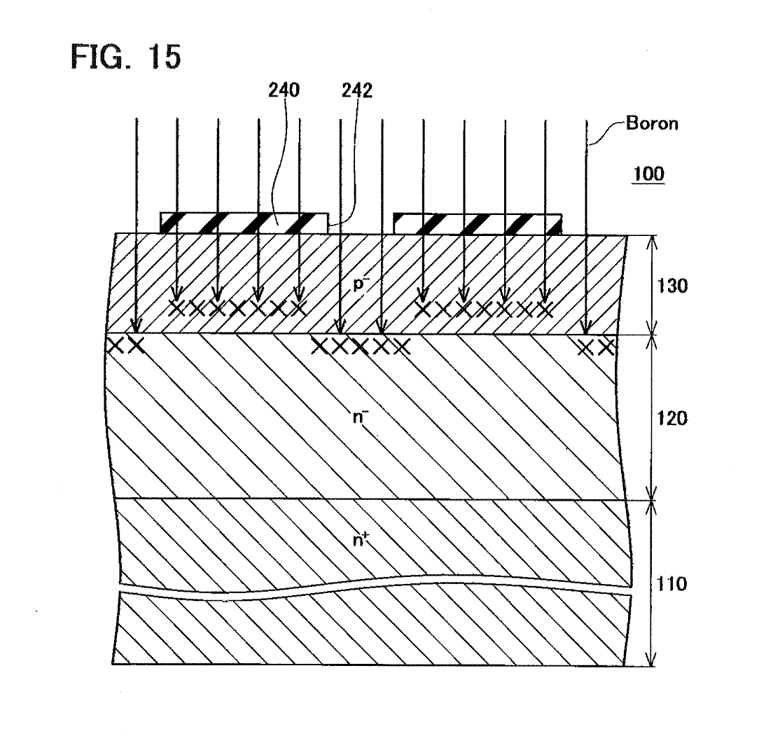

When manufacturing the MOSFET according to the second embodiment, steps S2 to S4 are performed in a same manner as in the first embodiment. In step S6, as shown in FIG. 15, a mask 240 that is thinner than the mask 140 according to the first embodiment (refer to FIG. 7) is formed on the upper surface of the semiconductor substrate 100. An opening 242 similar to the opening 142 of the mask 140 according to the first embodiment is formed on the mask 240. Once the mask 240 is formed, boron is irradiated toward the upper surface of the semiconductor substrate 100. Boron having penetrated the opening 242 stops at a depth corresponding to the deep region 46 in a similar manner to the first embodiment. Boron irradiated toward the mask 240 penetrates the mask 240 and is implanted into the semiconductor substrate 100. Since the boron having penetrated the mask 240 has consumed energy inside the mask 240, the boron having penetrated the mask 240 stops at a depth shallower than a depth corresponding to the deep region 46. In this case, by adjusting a thickness of the mask 240, the boron having penetrated the mask 240 is stopped at a depth corresponding to the base region 44. More specifically, boron is implanted so that an average of depths at which the boron having penetrated the mask 240 stops is approximately at a center in a depth direction of a region to become the base region 44. The MOSFET according to the second embodiment is completed by implanting boron as described above and subsequently executing steps S8 to S20 in a similar manner to the first embodiment.

With the manufacturing method according to the second embodiment, the mask 240 used in step S6 can be made thinner. The use of such a thin mask 240 enables the opening 242 to be formed at high accuracy. Therefore, with this manufacturing method, a range into which boron is implanted can be controlled with high accuracy and the deep region 46 can be formed with higher accuracy. As a result, according to this manufacturing method, a smaller MOSFET can be manufactured.

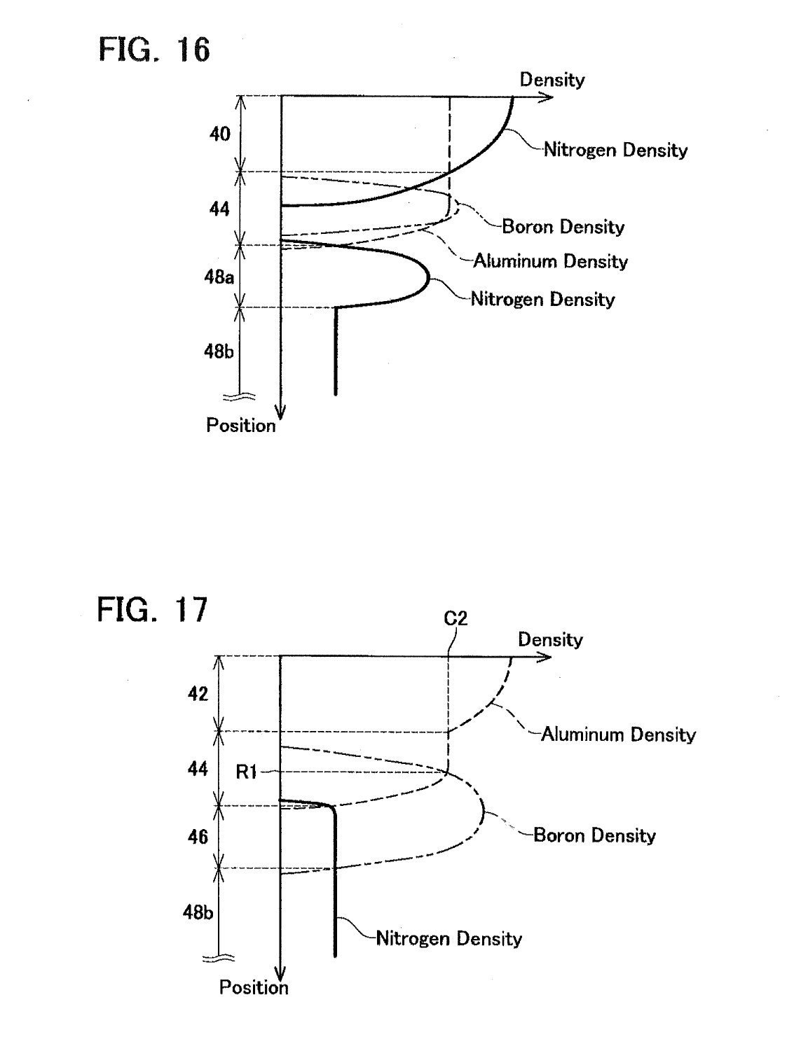

In the MOSFET according to the second embodiment described above, a density of boron in the base region 44 is lower than a density of aluminum in the base region 44. However, as shown in FIG. 16, the density of boron in the base region 44 may be set partially higher than the density of aluminum in the base region 44. Even with such a configuration, characteristics of the MOSFET are hardly affected.

In addition, by setting an average of depths at which the boron having penetrated the mask 240 stops to within a region to become the base region 44 as is the case with the manufacturing method according to the second embodiment, implantation of boron into the source region 40 and the high-density drift region 48a can be minimized. Accordingly, effects on the characteristics of the MOSFET can be minimized.

Moreover, while the base region 44 is formed by a p-type epitaxial layer in the first and second embodiments described above, the base region 44 may alternatively be formed by implanting aluminum into a semiconductor substrate.

In addition, in the first and second embodiments described above, as shown in FIG. 3, a density of aluminum C1 at a location where a density of aluminum and a density of boron are equivalent to each other in a vicinity of a border of the base region 44 and the deep region 46 is equal to or less than one-tenth of a peak value C2 of the density of aluminum in the base region 44. Accordingly, formation of crystal defects in the vicinity of the border of the base region 44 and the deep region 46 is minimized. In other words, when both boron and aluminum exist at a high density such as in a region in a vicinity of a depth R1 in FIG. 17, a large number of crystal defects are formed in the region in the vicinity of the depth R1. Therefore, a leakage current is likely to occur in the region in the vicinity of the depth R1. When the value C1 is equal to or less than one-tenth of the value C2 as is the case with the first and second embodiments, a large number of crystal defects is not formed and a leakage current is suppressed.

### Third Embodiment

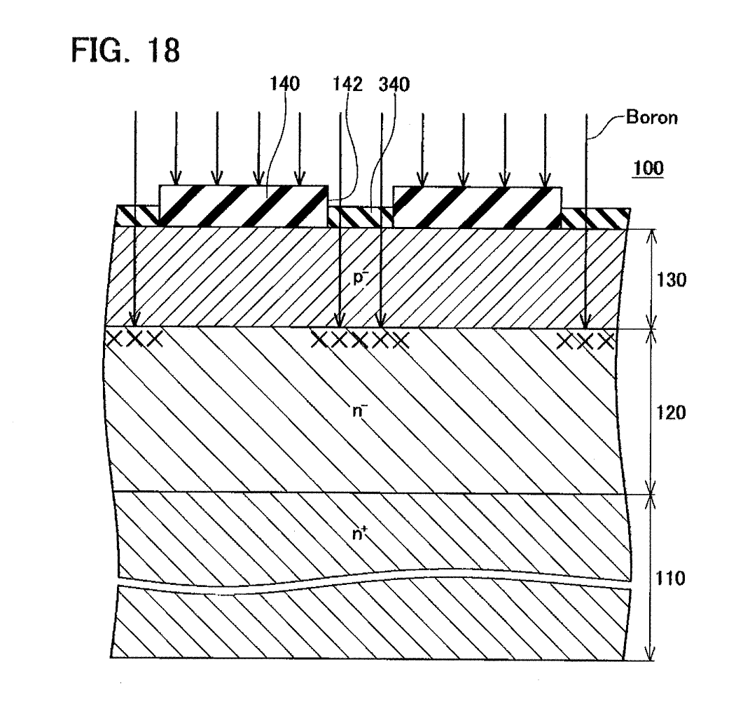

Next, a manufacturing method according to a third embodiment will be described. The manufacturing method according to the third embodiment is similar to the manufacturing method according to the first embodiment with respect to steps S2 and S4 and steps S8 to S20, and only differs from the manufacturing method according to the first embodiment with respect to step S6. In step S6 of the manufacturing method according to the third embodiment, as shown in FIG. 18, a mask 140 similar to that of the first embodiment is first formed on the upper surface of the semiconductor substrate 100. Next, a silicon oxide film 340 is formed on the upper surface of the semiconductor substrate 100 inside an opening 142. The silicon oxide film 340 is formed with a thickness of 100 nm or more (for example, around 200 nm). Next, as shown in FIG. 18, boron is irradiated toward the upper surface of the semiconductor substrate 100. In doing so, boron is irradiated by adjusting energy so that boron irradiated toward the mask 140 stops inside the mask 140 while boron irradiated toward the silicon oxide film 340 penetrates the silicon oxide film 340 and is implanted into the semiconductor substrate 100. In addition, boron is implanted so that the boron having passed through the opening 142 of the silicon oxide film 340 stops within the n-type epitaxial layer 120 in a vicinity of the p-type epitaxial layer 130. In other words, boron is implanted into a range in which the deep region 46 is to be formed. Moreover, in step S6 according to the third embodiment, the tilt angle θ1 described above may or may not be provided. In addition, the silicon oxide film 340 may be removed after completion of step S6 or after completion of step S8.

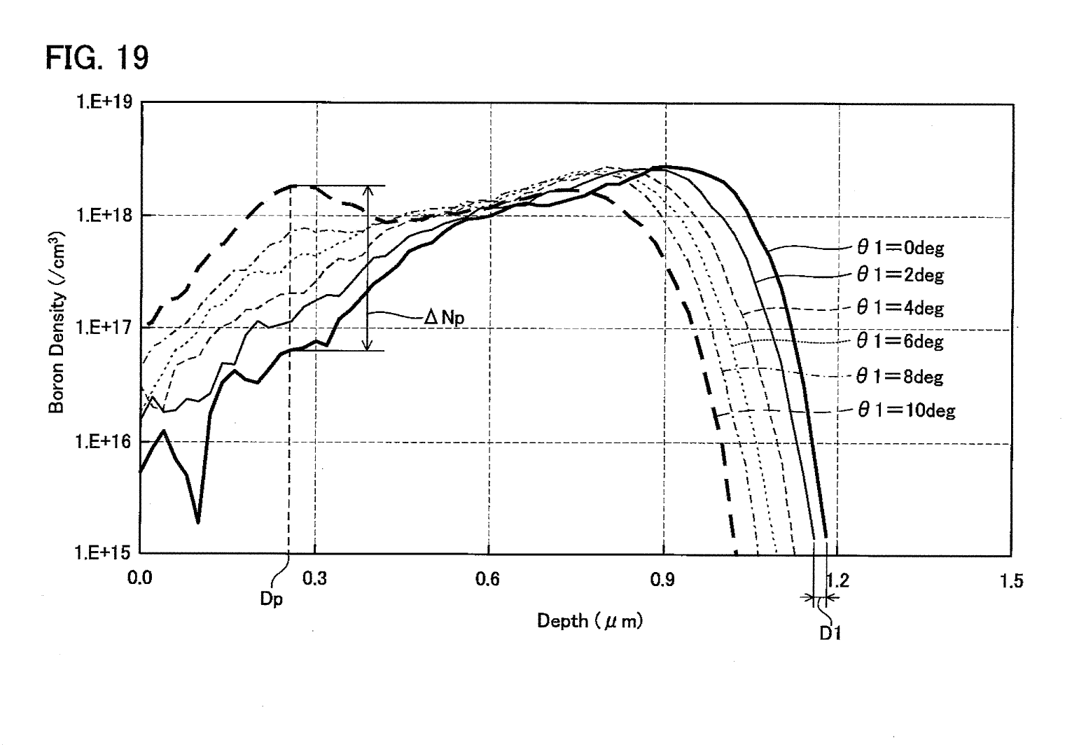

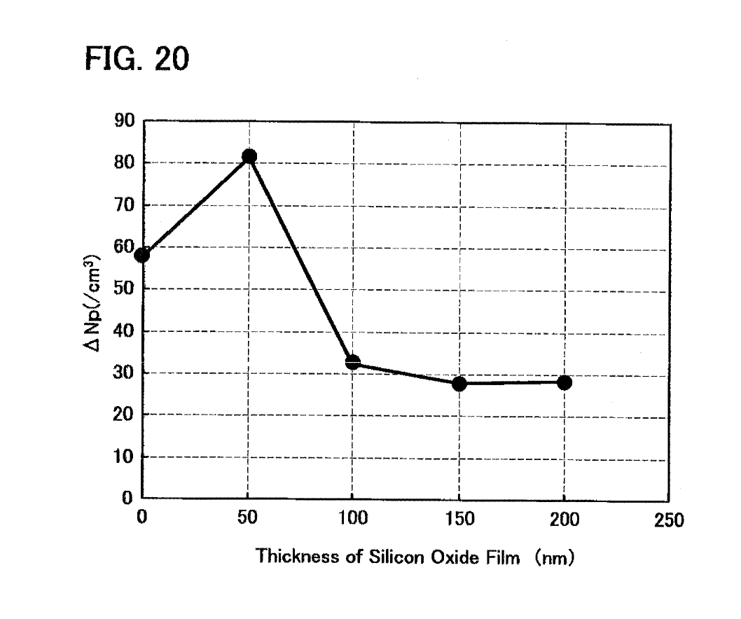

By implanting boron into the semiconductor substrate 100 through the silicon oxide film 340 as is the case with the manufacturing method according to the third embodiment, a variance in an implantation depth of boron can be suppressed. FIG. 19 shows a distribution of a density of boron in a depth direction of a SiC substrate having a silicon oxide film formed on an upper surface thereof when boron is implanted into the semiconductor substrate. FIG. 19 shows a distribution of a density of boron in a depth direction in a case where the boron is implanted through the silicon oxide film. In FIG. 19, a difference D1 in implantation depth is set smaller than in FIG. 13. In other words, with the manufacturing method according to the third embodiment, even when the tilt angle θ1 is 0 degrees, a phenomenon does not occur in which an implantation depth of boron becomes significantly deeper compared to a case where the tilt angle θ1 is 2 degrees or more. Furthermore, as shown in FIG. 19, even with the manufacturing method according to the third embodiment, two peaks of the density of boron is formed when the tilt angle θ1 is set to 10 degrees. Reference character ΔNp in FIGS. 13 and 19 denote differences between a density of boron when the tilt angle θ1 is set to 0 degrees and a density of boron when the tilt angle θ1 is set to 10 degrees at a depth Dp at which the second peak of the density of boron is formed. The density difference ΔNp is smaller in. FIG. 19 than in FIG. 13. As shown, when boron is implanted into the SiC substrate through the silicon oxide film, even if an error occurs in the tilt angle θ1 upon implantation, a variance in an implantation depth of boron is less likely to occur and, at the same time, a variance in a density of boron at the depth Dp is less likely to occur. Therefore, with the manufacturing method according to the third embodiment, a variance in characteristics of mass-produced MOSFETs can be suppressed.

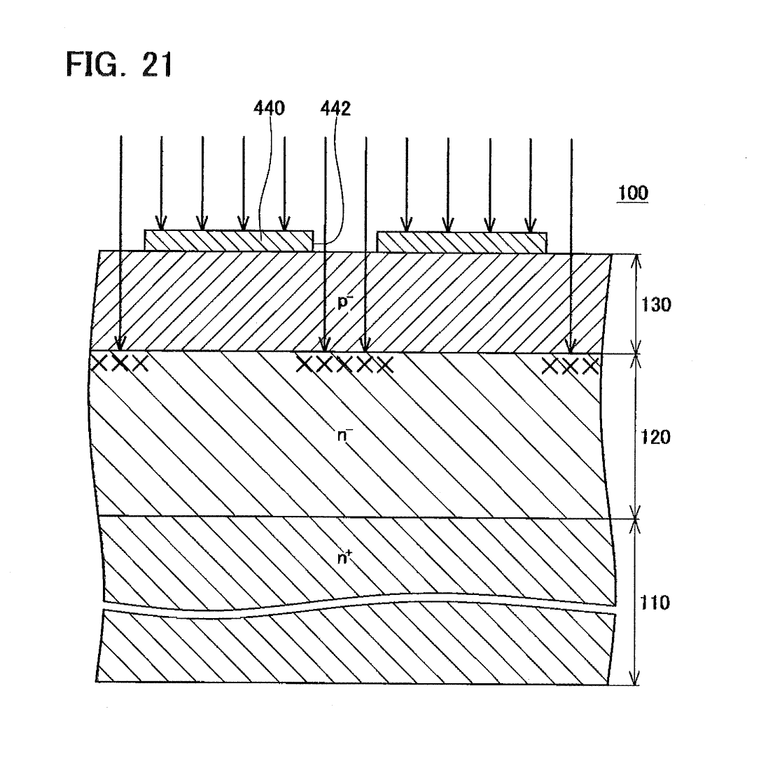

In addition, FIG. 20 shows a relationship between a thickness of a silicon oxide film and the density difference ΔNp described above. As shown in FIG. 20, when the thickness of the silicon oxide film equals or exceeds 100 nm, the density difference ΔNp becomes extremely small. Therefore, the thickness of the silicon oxide film is more favorably set to 100 nm or more as is the case with the manufacturing method according to the third embodiment.

### Fourth Embodiment

Next, a manufacturing method according to a fourth embodiment will be described. The manufacturing method according to the fourth embodiment is similar to the manufacturing method according to the first embodiment with respect to steps S2 and S4 and steps S8 to S20, and only differs from the manufacturing method according to the first embodiment with respect to step S6. In step S6 of the manufacturing method according to the fourth embodiment, as shown in FIG. 21, a metallic mask 440 is first formed on the upper surface of the semiconductor substrate 100. The metallic mask 440 is thinner than the mask 140 according to the first embodiment. An opening 442 similar to the opening 142 of the mask 140 according to the first embodiment is formed on the metallic mask 440. Next, as shown in FIG. 21, boron is irradiated toward the upper surface of the semiconductor substrate 100. Since the mask 440 is thin but made of metal, the boron irradiated toward the mask 440 stops inside the mask 440. On the other hand, boron is implanted into the semiconductor substrate 100 in a range in which the opening 442 is formed. In other words, boron is implanted into a range in which the deep region 46 is to be formed. As shown, even with the manufacturing method according to the fourth embodiment, boron can be implanted into a range in which the deep region 46 is to be formed. In addition, since the metallic mask 440 is highly capable of stopping boron, boron can be stopped even when the mask 440 is thin. When the mask 440 is thin, the opening 442 can be formed with high accuracy. Therefore, with this manufacturing method, a range into which boron is implanted can be controlled with high accuracy and the deep region 46 can be formed with higher accuracy. As a result, according to this manufacturing method, a smaller MOSFET can be manufactured.

While a MOSFET has been described in the first to fourth embodiments above, the techniques disclosed in the present specification can also be used on other switching devices (for example, an IGBT) having a trench type gate electrode.

While specific examples of the present disclosure have been described in detail, such specific examples are merely illustrative and are not intended to limit the scope of claims. Techniques described in the scope of claims include various modifications and changes made to the specific examples illustrated above. It is to be understood that the technical elements described in the present specification and the drawings exhibit technical usefulness solely or in various combinations thereof, and shall not be limited to the combinations described in the claims at the time of filing. Furthermore, the techniques illustrated in the present specification and the drawings are to achieve a plurality of objectives at the same time, whereby technical usefulness is exhibited by attaining any one of such objectives.

What is claimed is:

1. A method for manufacturing a switching device,
the switching device comprising:
a semiconductor substrate,
a trench formed on an upper surface of the semiconductor substrate,
a gate insulating film covering an inner surface of the trench, and
a gate electrode located within the trench;
the semiconductor substrate comprising:
a first semiconductor region of n-type and being in contact with the insulating film on a side surface of the trench,
a second semiconductor region of p-type, positioned under the first semiconductor region, and being in contact with the insulating film on the side surface of the trench,
a third semiconductor region of n-type, positioned under the second semiconductor region, and being in contact with the insulating film on the side surface of the trench, and
a fourth semiconductor region of p-type, positioned in a range deeper than the second semiconductor region, being consecutive with the second semiconductor region, and facing the gate insulating film via the third semiconductor region,
the method comprising:
forming the second semiconductor region in which aluminum is doped; and
implanting boron into a range in the semiconductor substrate in which the fourth semiconductor region is to be formed.

2. The method of claim 1, wherein in the implanting, boron is irradiated toward the upper surface of the semiconductor substrate in a state where a mask having an opening is set on the upper surface of the semiconductor substrate, wherein boron having passed through the opening is implanted into the range in which the fourth semiconductor region is to be formed, and boron having penetrated the mask is implanted into a range corresponding to the second semiconductor region.

3. The method of clam 2, wherein in the implanting, boron is implanted so that an average of depths at which boron having penetrated the mask stops in the semiconductor substrate is within the range corresponding to the second semiconductor region.

4. The method of claim 1, further comprising forming a fifth semiconductor region by irradiating p-type impurities toward the upper surface of the semiconductor substrate in the state where the same mask as that used in the implanting is set on the upper surface of the semiconductor substrate, wherein the fifth semiconductor region is exposed at the upper surface of the semiconductor substrate, is consecutive with the second semiconductor region, and has a higher density of the p-type impurities than that in the second semiconductor region.

5. The method of clam 1, further comprising implanting n-type impurities into a specific range between the range corresponding to the fourth semiconductor region and a range corresponding to the gate insulating film.

6. The method of claim 5, wherein in the implanting the n-type impurities into the specific range, the n-type impurities are irradiated toward the upper surface of the semiconductor substrate in a state where a mask having an opening is set on the upper surface of the semiconductor substrate, wherein the n-type impurities having passed through the opening are implanted into the specific range, and
the method further comprises irradiating the n-type impurities toward the upper surface of the semiconductor substrate in the state where the same mask as that used in the implanting the n-type impurities into the specific range is set on the upper surface of the semiconductor substrate, wherein the n-type impurities having passed through the opening are implanted into a range in which the first semiconductor region is to be formed.

7. The method of claim 1, wherein
the semiconductor substrate is made of SiC, and
in the implanting, boron is implanted at a tilt angle with respect to a (0001) plane or a (000-1) plane of the semiconductor substrate.

8. The method of claim 7, wherein the tilt angle is equal to or more than 2 degrees and equal to or less than 8 degrees.

9. The method of claim 1, wherein in the implanting, boron is irradiated toward the upper surface of the semiconductor substrate in a state where a mask having an opening is set on the upper surface of the semiconductor substrate and an oxide silicon film is located on the upper surface of the semiconductor substrate within the opening, wherein boron having penetrated the oxide silicon is implanted into the range in which the fourth semiconductor region is to be formed.

10. The method of claim 9, wherein a thickness of the oxide silicon is equal to or more than 100 nm.

11. The method of claim 1, wherein in the implanting, boron is irradiated toward the upper surface of the semiconductor substrate in a state where a mask having an opening is set on the upper surface of the semiconductor substrate, wherein boron having passed through the opening is implanted into the range in which the fourth semiconductor region is to be formed.

12. A switching device comprising:
a semiconductor substrate;
a trench formed on an upper surface of the semiconductor substrate;
a gate insulating film covering an inner surface of the trench; and
a gate electrode located within the trench,
wherein the semiconductor substrate comprises:
a first semiconductor region of n-type and being in contact with the insulating film;
a second semiconductor region of p-type, positioned under the first semiconductor region, and being in contact with the insulating film;
a third semiconductor region of n-type, positioned under the second semiconductor region, and being in contact with the insulating film; and
a fourth semiconductor region of p-type, positioned in a range deeper than the second semiconductor region, being consecutive with the second semiconductor region, and facing the gate insulating film via the third semiconductor region,
wherein a density of aluminum is higher than a density of boron in at least a part of the second semiconductor region, and
wherein the density of the boron is higher than the density of the aluminum in the fourth semiconductor region.

13. The switching device of claim 12, wherein aluminum and boron are doped in the second semiconductor region.

14. The switching device of claim 13, wherein a peak value of the density of boron in a distribution of the density of boron along a depth direction in the first, second, and third semiconductor regions is within the second semiconductor region.

15. The switching device of claim 12, wherein the density of the n-type impurities is higher in a specific range between the fourth semiconductor region and the gate insulating film than in a range outside the specific range and in the third semiconductor region being in contact with the specific range.

16. The switching device of claim 12, wherein the density of aluminum at a position which is in a vicinity of a border of the second semiconductor region and the fourth semiconductor region is equal to or less than one-tenth of a peak value of the density of aluminum in the second semiconductor region, wherein the position is where the density of aluminum and the density of boron are identical to each other.
